(19) United States
(12) Patent Application Publication
(10) Pub. No.: US 2025/0022692 A1
(43) Pub. Date: Jan. 16, 2025

(54) ELECTROSTATIC CHUCK DEVICE AND SUBSTRATE PROCESSING APPARATUS INCLUDING THE SAME

(71) Applicant: ASM IP Holding B.V., Almere (NL)

(72) Inventor: Koji Tanaka, Tokyo (JP)

(21) Appl. No.: 18/764,584

(22) Filed: Jul. 5, 2024

Related U.S. Application Data
(60) Provisional application No. 63/525,802, filed on Jul. 10, 2023.

(51) Int. Cl. H01J 37/32; H01L 21/683

(52) U.S. Cl. CPC H01J 37/32715; H01J 37/32449; H01L 21/6833; H01J 2237/2007

(57) ABSTRACT

An electrostatic chuck device of the present disclosure includes a stage having on its upper surface a circular substrate attached area (where D_{S} is the diameter of the area) to which a circular substrate to be processed is electrostatically attached; and an ESC electrode embedded in the stage, having a diameter D_{E1} larger than the diameter D_{S} of the substrate attached area, and arranged concentrically with the center of the substrate attached area in plan view; wherein the substrate to be processed is electrostatically attached to the upper surface of the stage by the Johnsen-Rahbek force by applying a DC voltage to the ESC electrode, and the stage includes a high-resistance ring-shaped portion in an outer portion arranged outside the substrate attached area in plan view, which is configured to suppress current leaking from the outer portion to the plasma space when the DC voltage is applied.

### CROSS-REFERENCE TO RELATED APPLICATIONS

This application claims priority to U.S. Provisional Patent Application Ser. No. 63/525,802 filed Jul. 10, 2023 titled ELECTROSTATIC CHUCK DEVICE AND SUBSTRATE PROCESSING APPARATUS INCLUDING THE SAME, the disclosure of which is hereby incorporated by reference in its entirety.

### FIELD OF INVENTION

The present disclosure is related to an electrostatic chuck device and a substrate processing apparatus.

### BACKGROUND OF THE DISCLOSURE

An electrostatic chuck, which fixes a substrate to be processed with electrostatic attraction force, can hold the substrate to be processed flat and is suitable for controlling the substrate temperature during plasma processing. Therefore, it is used to hold the substrate when performing plasma processing such as dry etching, sputtering, and plasma CVD.

In the electrostatic chuck, an internal electrode (ESC electrode) is embedded in a disk-shaped ceramic plate having approximately the same diameter as that of the substrate to be processed, for example, a semiconductor wafer, which is electrostatically attracted and is fixed on the ceramic plate by applying a DC voltage to the internal electrode (see, JP Patent Application Publication No. 2020-088195).

The electrostatic chuck includes a type using the Coulomb force and a type using the Johnson-Rahbek force. The main electrostatic attraction force in the type using the Coulomb force is the Coulomb force between different charges, which is generated by forming a capacitor with dielectric material as a capacitance located between the internal electrode and the semiconductor wafer and inducing opposite charge polarities between the internal electrode and the semiconductor wafer. On the other hand, the main electrostatic attraction force in the type using the Johnson Larbeck-type is the Johnson-Rahbek force (in the following, it is sometimes abbreviated to JR force.), which is generated when a minute current flowing through the dielectric material induces charged polarization in a small gap at the interface between the semiconductor wafer and the dielectric material, and the positive and negative charges attract.

High-temperature plasma processing generally uses Johnson-Larbeck type electrostatic chuck with high electrostatic attraction force.

In electrostatic chucks, both reduction of leakage current for stable attraction force and uniformity of plasma are important.

JP Patent Application Publication No. 2020-088195 proposes to use an attraction electrode (ESC electrode) with a diameter smaller than the wafer and an auxiliary electrode to reduce the leakage current.

In the constitution disclosed in JP Patent Application Publication No. 2020-088195, the distance from the surface of a stage (ceramic plate) to the attraction electrode and the distance from the surface of the stage to the auxiliary electrode are different each other, resulting in a problem of poor plasma uniformity, especially near the edge of the wafer W. In addition, considering the manufacturing process, it is difficult to manufacture the electrode precisely due to deformation during sintering. Furthermore, although JP Patent Application Publication No. 2020-088195 only focuses on the resistance of the stage made of aluminum nitride (AlN), the problem that the chucking force is lowered due to increased leakage current at high temperatures is essentially caused by the fact that the resistance of the stage becomes small compared to the contact resistance with the wafer. Therefore, it is difficult to achieve both reduction of leakage current and the plasma uniformity by such a constitution.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

According to a first aspect of the present disclosure, there is provided an electrostatic chuck device used in a plasma space including: a stage having on its upper surface a circular substrate attached area (where D_{S} is the diameter of the area) to which a circular substrate to be processed is electrostatically attached; and an ESC electrode embedded in the stage, having a diameter D_{E1} larger than the diameter D_{S} of the substrate attached area, and arranged concentrically with the center of the substrate attached area in plan view; wherein the substrate to be processed is electrostatically attached to the substrate attached area of the stage by the Johnsen-Rahbek force by applying a DC voltage to the ESC electrode, and the stage includes a high-resistance ring-shaped portion in an outer portion arranged outside the substrate attached area in plan view, which is configured to suppress current leaking from the outer portion to the plasma space when the DC voltage is applied.

A second aspect of the present disclosure is the electrostatic chuck device according to the first aspect, wherein it includes a heater below the ESC electrode in the stage.

A third aspect of the present disclosure is the electrostatic chuck device according to the first or second aspect, wherein the high-resistance ring-shaped portion is made of a high-resistance material having a higher volume resistivity than that of the material of the portion of the stage between the substrate attached area and the ESC electrode.

A fourth aspect of the present disclosure is the electrostatic chuck device according to any one of the first to third aspects, wherein the high-resistance material of the high-resistance ring-shaped portion includes the same base material as the material of a portion other than the high-resistance ring-shaped portion, and the concentration of impurity elements in the high-resistance material of the high-resistance ring-shaped portion is different from that in the material of the portion other than the high-resistance ring-shaped portion.

A fifth aspect of the present disclosure is the electrostatic chuck device according to any one of the first to fourth aspects, wherein the high-resistance material of the high-resistance ring-shaped portion is aluminum nitride.

A sixth aspect of the present disclosure is the electrostatic chuck device according to the first or second aspect, wherein the high-resistance ring-shaped portion is a ring-shaped convex portion disposed so as to surround the substrate to be processed and protruding upward from the substrate attached area.

A seventh aspect of the present disclosure is the electrostatic chuck device according to the sixth aspect, wherein the ring-shaped convex portion is made of a high-resistance material having a higher volume resistivity than that of the material of the portion of the stage between the substrate attached area and the ESC electrode.

A eighth aspect of the present disclosure is the electrostatic chuck device according to the sixth or seventh aspect, the high-resistance material of the ring-shaped convex portion includes the same base material as the material of a portion other than the ring-shaped convex portion, and the concentration of impurity elements in the high-resistance material of the ring-shaped convex portion is different from that in the material of the portion other than the ring-shaped convex portion.

A ninth aspect of the present disclosure is the electrostatic chuck device according to the first or second aspect, wherein the high-resistance ring-shaped portion is a separate, ring-shaped member disposed so as to surround the substrate to be processed.

A tenth aspect of the present disclosure is the electrostatic chuck device according to the ninth aspect, wherein the ring-shaped member includes multiple protrusions on its back surface.

An eleventh aspect of the present disclosure is the electrostatic chuck device according to the ninth or tenth aspect, wherein the ring-shaped member is made of a high-resistance material having a higher volume resistivity than that of the material of the portion of the stage between the substrate attached area and the ESC electrode.

A twelfth aspect of the present disclosure is the electrostatic chuck device according to the third aspect, wherein, as the high-resistance ring-shaped portion, a ring-shaped member is separately disposed on the high-resistance ring-shaped portion made of a high-resistance material so as to surround the substrate to be processed.

A thirteenth aspect of the present disclosure is the electrostatic chuck device according to the twelfth aspect, wherein the ring-shaped member includes multiple protrusions on its back surface.

A fourteenth aspect of the present disclosure is the electrostatic chuck device according to the twelfth or thirteenth aspect, wherein the material of the ring-shaped member is the same as that of the high-resistance ring-shaped portion made of a high-resistance material.

According to a fifteenth aspect of the present disclosure, there is provided an electrostatic chuck device used in a plasma space, including: a stage having on its upper surface a circular substrate attached area (where D_{S} is the diameter of the area) to which a circular substrate to be processed is electrostatically attached; an ESC electrode embedded in the stage, having a diameter D_{E2} which is smaller than or approximately the same as the diameter D_{S} of the substrate attached area, and arranged concentrically with the center of the substrate attached area in plan view; and an RF electrode for plasma generation which is embedded in the stage at the same depth as the ESC electrode, and is in an outer portion arranged outside the substrate attached area in plan view; wherein the substrate to be processed is electrostatically attached to the substrate attached area of the stage by the Johnsen-Rahbek force by applying a DC voltage to the ESC electrode.

A sixteenth aspect of the present disclosure is the electrostatic chuck device according to the fifteenth aspect, wherein the RF electrode is grounded through a matching circuit including a capacitor and/or a coil so that the RF electrode and the ESC electrode have equivalent impedance.

According to a seventeenth aspect of the present disclosure, there is provided a substrate processing apparatus including: a chamber; an electrostatic chuck device according to any one of the first to sixteenth aspects, provided in the chamber; and a shower head provided above the electrostatic chuck device.

According to an eighteenth aspect of the present disclosure, there is provided a substrate processing apparatus including: a chamber; an electrostatic chuck device provided in the chamber; a shower head provided above the electrostatic chuck device; and a flow control ring having a shape surrounding the electrostatic chuck device, wherein the electrostatic chuck device includes a stage having on its upper surface a circular substrate attached area (where D₁ is the diameter of the area) to which a circular substrate to be processed (where D₀ is the diameter of the substrate) is electrostatically attached, and an ESC electrode embedded in the stage, having a diameter D_{E2} which is smaller than or approximately the same as the diameter D₁ of the substrate attached area, and arranged concentrically with the center of the substrate attached area in plan view, and wherein the diameter D₁ of the substrate attached area is equal to the diameter D₀ of the substrate to be processed within a range of ±5 mm, and the flow control ring is made of metal and acts as an RF electrode for plasma generation.

According to a nineteenth aspect of the present disclosure, there is provided a substrate processing apparatus including: a chamber; an electrostatic chuck device provided in the chamber; a shower head provided above the electrostatic chuck device; and a flow control ring having a shape surrounding the electrostatic chuck device, wherein the electrostatic chuck device includes a stage having on its upper surface a circular substrate attached area (where D₁ is the diameter of the area) to which a circular substrate to be processed (where D₀ is the diameter of the substrate) is electrostatically attached, and an ESC electrode embedded in the stage, having a diameter D_{E2} which is smaller than or approximately the same as the diameter D₁ of the substrate attached area, and arranged concentrically with the center of the substrate attached area in plan view, and wherein the diameter D₁ of the substrate attached area is equal to the diameter D₀ of the substrate to be processed within a range of ±5 mm, the flow control ring is made of ceramic, and an RF electrode for plasma generation is embedded in the flow control ring.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1A is a schematic cross-sectional view of the electrostatic chuck device according to the first embodiment, and shows a state in which a substrate W to be processed is placed.

FIG. 1B is a schematic cross-sectional view of the electrostatic chuck device according to the first embodiment, and shows a state in which a substrate W to be processed is not placed.

FIG. 2 is a conceptual diagram to illustrate the leakage current.

FIG. 3 is a schematic cross-sectional view of the electrostatic chuck device according to a modified example of the first embodiment.

FIG. 4A is a schematic cross-sectional view of the electrostatic chuck device according to the second embodiment.

FIG. 4B is a schematic cross-sectional view of the electrostatic chuck device according to a modified example of the second embodiment.

FIG. 5A is a schematic cross-sectional view of the electrostatic chuck device according to the third embodiment.

FIG. 5B is a schematic cross-sectional view of the electrostatic chuck device according to a modified example of the third embodiment.

FIG. 6A is a schematic cross-sectional view of the electrostatic chuck device according to another modified example of the third embodiment.

FIG. 6B is a schematic cross-sectional view of the electrostatic chuck device according to another modified example of the third embodiment.

FIG. 7 is a schematic cross-sectional view of an example of a substrate processing apparatus of the present disclosure equipped with the electrostatic chuck device described above.

FIG. 8 is a diagram simply expressing the configuration of FIG. 7 in order to explain the operation during substrate processing in an easy-to-understand manner.

FIG. 9A is a schematic cross-sectional view of the electrostatic chuck device according to the fourth embodiment.

FIG. 9B is a schematic cross-sectional view of the electrostatic chuck device according to a modified example of the fourth embodiment.

FIG. 10A is a schematic cross-sectional view of a part of a modified example of the substrate processing apparatus shown in FIG. 7.

FIG. 10B is a schematic cross-sectional view of a modified example of the substrate processing apparatus shown in FIG. 10A.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

FIGS. 1A and 1B are schematic cross-sectional views of the electrostatic chuck device according to the first embodiment. FIG. 1A shows a state in which a substrate W to be processed is placed, and FIG. 1B shows a state in which the substrate W to be processed is not placed.

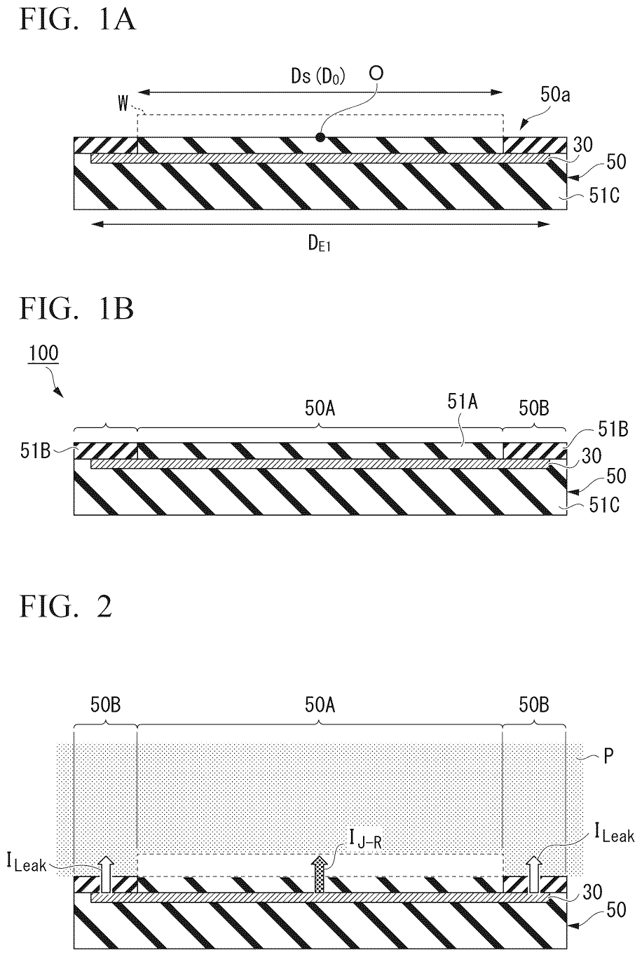

The electrostatic chuck device 100 shown in FIGS. 1A and 1B is an electrostatic chuck device used in a plasma space. The electrostatic chuck device 100 includes a stage 50 having on its upper surface 50a a circular substrate attached area 50A (where D_{S} is the diameter of the area) to which a circular substrate W to be processed is electrostatically attached, and an ESC electrode 30 embedded in the stage 50, having a diameter D_{E1} larger than the diameter D_{S} of the substrate attached area 50A, and arranged concentrically with the center O of the substrate attached area 50A in plan view. The substrate W to be processed is electrostatically attached to the upper surface 50a of the stage 50 by the Johnsen-Rahbek force by applying a DC voltage to the ESC electrode 30. The stage 50 has a high-resistance ring-shaped portion 51B in a ring-shaped outer peripheral area 50B arranged adjacent to the outside of the substrate adsorption area 50A in plan view, which suppresses leakage current leaking from the ring-shaped outer peripheral area 50B to the plasma space P (see FIG. 2) when a DC voltage is applied.

Reference sign 51C denotes a lower portion of the high-resistance ring-shaped portion 51B and a lower portion of the ESC electrode 30 in the stage 50.

The stage 50 is made of a dielectric material, for example, a ceramic material such as aluminum nitride (AlN), alumina, silicon carbide (SiC), boron nitride (BN), or the like. The ESC electrode 30 is made of, for example, a high melting-point metal such as tungsten, tantalum, molybdenum, niobium, ruthenium, hafnium, or the like. The shape of the ESC electrode 30 is, for example, plate-like, wire mesh-like, or punching metal-like.

Hereafter, the description will not be repeated because the materials and shapes of the stage and ESC electrode are similar in the following other embodiment.

FIG. 2 is a conceptual diagram to illustrate the leakage current.

In FIG. 2, when a DC voltage is applied to the ESC electrode 30 to generate the JR force, an unintended current flows from the ring-shaped outer peripheral area 50B where there is no wafer W, through the plasma space. The unintended current is a leakage current I_{Leak} shown in FIG. 2. When a DC voltage is applied to the ESC electrode 30 to generate the JR force, a minute current I_{J-R} shown in FIG. 2 is generated according to the resistance Rᵢₙ between the ESC electrode 30 and the circular substrate attached area 50A, the resistance Rₒᵤₜ between the ESC electrode 30 and the ring-shaped outer peripheral area 50B, and the DC voltage.

As mentioned above, the JR force is generated when the minute current I_{J-R} induces charging polarization at a small gap in the interface IF between the semiconductor wafer W and the dielectric material 50, and its positive and negative charges attract.

Leakage current I_{Leak} is the current flowing through the plasma space P from the ring-shaped outer peripheral area 50B where wafer W is not located. This leakage current I_{Leak} not only does not contribute to the JR force, but also impairs the uniformity of the plasma near the ring-shaped outer peripheral area 50B, i.e., near the edge of the wafer W.

The electrostatic chuck device of the present disclosure includes a high-resistance ring-shaped portion, and is designed to reduce the leakage current I_{Leak} by increasing the resistance Rₒᵤₜ against the resistance Rᵢₙ, thereby improving the uniformity of plasma near the edge of the wafer W. In addition, taking into account the uniformity of the plasma, the diameter D_{E1} of the ESC electrode should be sufficiently large for the diameter D₀ of the wafer W (substantially equal to the diameter D_{S} of the circular substrate attached area 50A). D_{E1} is, for example, at 10 mm larger than Ds.

In the electrostatic chuck device shown in FIGS. 1A and 1B, the high-resistance ring-shaped portion 51B consists of a high-resistivity material with a higher volume resistivity than the stage material in a portion (wafer contact portion) 51A between the circular substrate attached area 50 A and the ESC electrode 30.

The resistance Rₒᵤₜ is preferably greater than 10 times the resistance Rᵢₙ (that is, Rₒᵤₜ>10 Rᵢₙ). It is preferable that each material is selected so that the volume resistivity □_{B} [□ cm] of the high-resistance material constituting the high-resistance ring-shaped portion (a portion where wafer does not contact) 51B, and the volume resistivity □_{A} [□ cm] of the low-resistance material constituting the wafer contact portion 51A satisfy Rₒᵤₜ>10 Rᵢₙ.
In addition, the electrostatic chuck device shown in FIGS. 1A and 1B is a case where the lower portion 51C located below the high-resistance ring-shaped portion 51B and below the ESC electrode 30 are also made of the same material as the low-resistance material of the wafer contact portion 51A.

The resistance of the high-resistance ring-shaped portion 51B is determined by the following formula (1).

$$\begin{matrix}[ Formula 1 ] & \\ R = ρ \frac{l}{S} & ( 1 )\end{matrix}$$

where R, □, l and S in formula (1) are the resistance, volume resistivity (resistivity), thickness and area of the high-resistance ring-shaped portion 51B, respectively.

The electrostatic chuck device according to the first embodiment adopts a configuration in which the material of the high-resistance ring-shaped portion 51B is a material with a high volume resistivity □ to increase the resistance of the high-resistance ring-shaped portion 51B and reduce the leakage current.

In the electrostatic chuck device shown in FIGS. 1A and 1B, the high-resistance ring-shaped portion 51B is arranged so as to fill the space between the top surface 50a and the ESC electrode 30, but it may be arranged so as to fill a part of the space between the top surface 50a and the ESC electrode 30, or extended to a part of the wafer contact portion 51A.

Also, in the electrostatic chuck device shown in FIGS. 1A and 1B, the stage 50 is made of a material with the same volume resistivity except for the high-resistance ring-shaped portion 51B, but it is not limited to this. For example, the portion below the ESC electrode 30 may be composed of a material with a volume resistivity different from that of the wafer contact portion 51A.

In the electrostatic chuck device shown in FIGS. 1A and 1B, a heater (see, reference sign 28 in FIG. 7) may be provided below the ESC electrode 30 in the stage 50 as shown in FIG. 7.

The electrostatic chuck device 101 of a modified example shown in FIG. 3 is a constitution that includes the stage 50-1 in which the portion 51-1C below the high-resistance ring-shaped portion 51-1B and the ESC electrode 30 is made of the same as the high-resistance material of the high-resistance ring-shaped portion 51-1B. Components in common with those described above are described using the reference signs used in FIGS. 1A and 1B.

The electrostatic chuck device 101 shown in FIG. 3 includes a stage 50-1 having on its upper surface 50a a circular substrate attached area 50-1A (where D_{S} is the diameter of the area) to which a circular substrate W to be processed is electrostatically attached, and an ESC electrode 30 embedded in the stage 50-1, having a diameter D_{E1} larger than the diameter D_{S} of the substrate attached area 50-1A, and arranged concentrically with the center O of the substrate attached area 50-1A in plan view. The substrate W to be processed is electrostatically attached to the upper surface 50a of the stage 50-1 by the Johnsen-Rahbek force by applying a DC voltage to the ESC electrode 30. The stage 50-1 has a high-resistance ring-shaped portion 51-1B in a ring-shaped outer peripheral area 50-1B arranged adjacent to the outside of the substrate adsorption area 50-1A in plan view, which suppresses leakage current leaking from the ring-shaped outer peripheral area 50-1B to the plasma space P when a DC voltage is applied.

The high-resistance material constituting the high-resistance ring-shaped portion 51B shown in FIG. 1B or the high-resistance ring-shaped portion 51-1B shown in FIG. 3 is the same base material as a portion other than the high-resistance ring-shaped portion, but the composition can be different in the concentration of impurity elements. Here, the base material means the main material. In this constitution, since the difference in the coefficient of thermal expansion between the high-resistance material and the low-resistance material is small, peeling between the high-resistance material portion and the low-resistance material portion is unlikely even when the stage 50 is repeatedly heated and cooled.

Examples of such materials include aluminum nitride. By varying the content of impurity elements contained in aluminum nitride, it can be used as a high-resistance material and a low-resistance material.

In the electrostatic chuck device shown in FIG. 3, a heater (see, reference sign 28 in FIG. 7) may be provided below the ESC electrode 30 in the stage 50-1.

The stages described above can be made in one piece by known methods, e.g., sintering.

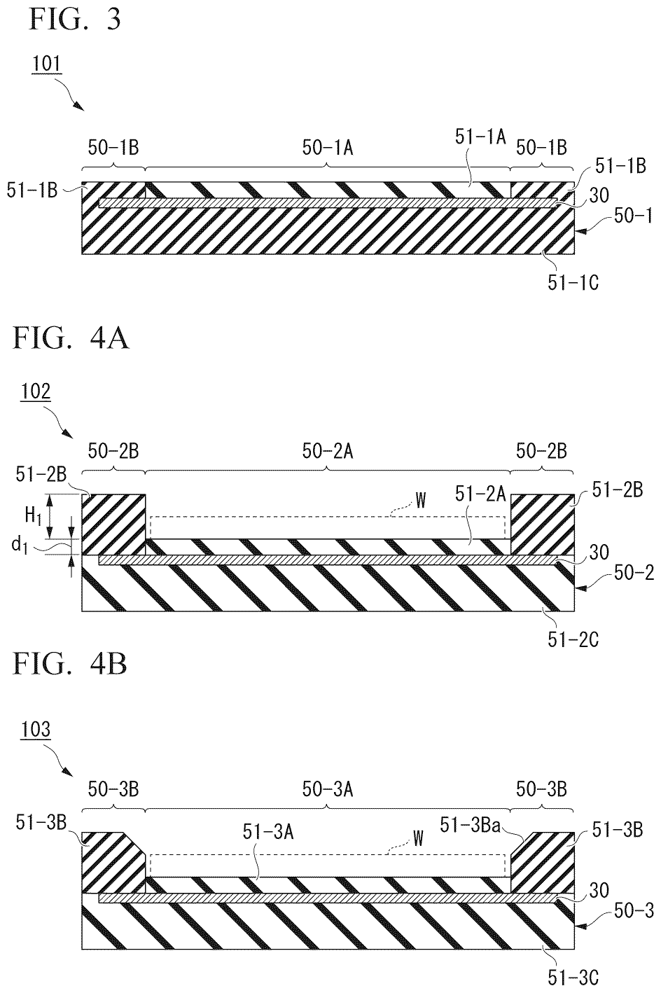

FIG. 4A is a schematic cross-sectional view of the electrostatic chuck device according to the second embodiment.

The electrostatic chuck device 102 shown in FIG. 4A is an electrostatic chuck device used in a plasma space. The electrostatic chuck device 102 includes a stage 50-2 having on its upper surface 50a a circular substrate attached area 50-2A (where D_{S} is the diameter of the area) to which a circular substrate W to be processed is electrostatically attached, and an ESC electrode 30 embedded in the stage 50-2, having a diameter D_{E1} larger than the diameter D_{S} of the substrate attached area 50-2A, and arranged concentrically with the center O of the substrate attached area 50-2A in plan view. The substrate W to be processed is electrostatically attached to the upper surface 50a of the stage 50-2 by the Johnsen-Rahbek force by applying a DC voltage to the ESC electrode 30. The stage 50-2 has a high-resistance ring-shaped portion 51-2B in a ring-shaped outer peripheral area 50-2B arranged adjacent to the outside of the substrate adsorption area 50-2A in plan view, which suppresses leakage current leaking from the ring-shaped outer peripheral area 50-2B to the plasma space P (see FIG. 2) when a DC voltage is applied.

The high-resistance ring-shaped portion 51-2B is arranged to surround the substrate W to be processed, and is a ring-shaped convex portion protruding upward from the substrate attached region 50-2A.

The electrostatic chuck device according to the second embodiment adopts a constitution in which the thickness l, which is contained in formula (1) described above, of the high-resistance ring-shaped portion 51-2B is thick to increase the resistance and reduce the leakage current.

The resistance Rᵢₙ between the ESC electrode 30 and the substrate attached region 50-2A and the resistance Rₒᵤₜ of the ring-shaped convex portion 51-2B, which is a high-resistance ring-shaped portion and is preferably greater than 10 times the resistance Rᵢₙ (that is, Rₒᵤₜ>10 Rᵢₙ). The ring-shaped convex portion 51-2B as a high-resistance ring-shaped portion is preferably made of a high-resistance material with a higher volume resistivity than the stage material in the portion (wafer contact portion) 51-2A between the substrate attached area 50-2A and the ESC electrode 30. This is because, in addition to the thickness in formula (1), as in the first embodiment, the resistance of the ring-shaped convex portion 51-2B can be made larger by the effect of large volume resistivity.

H₁, d₁ in the thickness (H₁+d₁) of the ring-shaped convex portion 51-2B can be set to satisfy Rₒᵤₜ>10 Rᵢₙ. H₁ is the thickness (height) protruding upward from the substrate attached area 50-2A, and d₁ is the thickness from the substrate attached area 50-2A to the top surface of the ESC electrode 30.
As an example of the thickness d₁, it can be about several mm. More specifically, it can be about 1 mm to 2 mm.

As in the first embodiment, the high-resistance material constituting the ring-shaped convex portion 51-2B is the same base material as a portion other than the high-resistance ring-shaped portion, but the composition can be different in the concentration of impurity elements. In this constitution, since the difference in the coefficient of thermal expansion between the high-resistance material and the low-resistance material is small, peeling between the ring-shaped convex portion 51-2B as the high-resistance material portion and the low-resistance material portion is unlikely even when the stage 50-2 is repeatedly heated and cooled.

Examples of such materials include aluminum nitride. By varying the content of impurity elements contained in aluminum nitride, it can be used as a high-resistance material and a low-resistance material.

In the electrostatic chuck device shown in FIG. 4A, the lower portion 51-2C located below the ring-shaped convex portion 51-2B and below the ESC electrode 30 are also made of the same material as the low-resistance material of the wafer contact portion 51-2A.

In the electrostatic chuck device shown in FIG. 4A, a heater (see, reference sign 28 in FIG. 7) may be provided below the ESC electrode 30 in the stage 50-2.

The stage described above can be made in one piece by known methods, e.g., sintering.

FIG. 4B shows a modified example of the electrostatic chuck device according to the second embodiment.

The electrostatic chuck device 103 of a modified example shown in FIG. 4B differs from the electrostatic chuck device 102 shown in FIG. 4A in that the tapered part 51-3Ba is formed on the wafer W side of the ring-shaped convex portion 51-3B. Having a tapered structure can reduce the concentration of plasma due to the edge effect. It is preferable to have a tapered part on the opposite side of the wafer W to prevent abnormal discharge.
For the same purpose, a structure having a round structure may be used instead of a tapered structure.

The electrostatic chuck device 103 as a modified example shown in FIG. 4B includes a stage 50-3 having on its upper surface 50a a circular substrate attached area 50-3A (where D_{S} is the diameter of the area) to which a circular substrate W to be processed is electrostatically attached, and an ESC electrode 30 embedded in the stage 50-3, having a diameter D_{E1} larger than the diameter D_{S} of the substrate attached area 50-3A, and arranged concentrically with the center O of the substrate attached area 50-3A in plan view. The substrate W to be processed is electrostatically attached to the upper surface 50a of the stage 50-3 by the Johnsen-Rahbek force by applying a DC voltage to the ESC electrode 30. The stage 50-3 has a ring-shaped convex portion 51-3B as a high-resistance ring-shaped portion in a ring-shaped outer peripheral area 50-3B arranged adjacent to the outside of the substrate adsorption area 50-3A in plan view, which suppresses leakage current leaking from the ring-shaped outer peripheral area 50-3B to the plasma space P when a DC voltage is applied.

The ring-shaped convex portion 51-3B as a high-resistance ring-shaped portion is preferably made of a high-resistance material with a higher volume resistivity than the stage material in the portion (wafer contact portion) 51-3A between the substrate attached area 50-3A and the ESC electrode 30. This is because, in addition to the thickness in formula (1), as in the first embodiment, the resistance of the ring-shaped convex portion 51-3B can be made larger by the effect of large volume resistivity.

In the electrostatic chuck device shown in FIG. 4B, the lower portion 51-3C located below the ring-shaped convex portion 51-3B and below the ESC electrode 30 are also made of the same material as the low-resistance material of the wafer contact portion 51-3A.

In the electrostatic chuck device shown in FIG. 4B, a heater (see, reference sign 28 in FIG. 7) may be provided below the ESC electrode 30 in the stage 50-3.

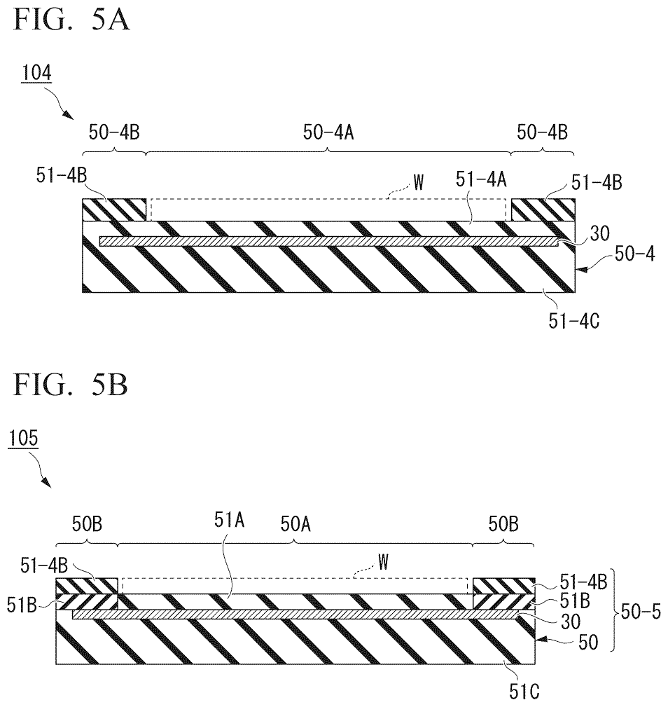

FIG. 5A is a schematic cross-sectional view of the electrostatic chuck device according to the third embodiment.

The electrostatic chuck device 104 shown in FIG. 5A is an electrostatic chuck device used in a plasma space. The electrostatic chuck device 104 includes a stage 50-4 having on its upper surface 50a a circular substrate attached area 50-4A (where D_{S} is the diameter of the area) to which a circular substrate W to be processed is electrostatically attached, and an ESC electrode 30 embedded in the stage 50-4, having a diameter D_{E1} larger than the diameter D_{S} of the substrate attached area 50-4A, and arranged concentrically with the center O of the substrate attached area 50-4A in plan view. The substrate W to be processed is electrostatically attached to the upper surface 50a of the stage 50-4 by the Johnsen-Rahbek force by applying a DC voltage to the ESC electrode 30. The stage 50-4 has a high-resistance ring-shaped portion 51-4B in a ring-shaped outer peripheral area 50-4B arranged adjacent to the outside of the substrate adsorption area 50-4A in plan view, which suppresses leakage current leaking from the ring-shaped outer peripheral area 50-4B to the plasma space P (see FIG. 2) when a DC voltage is applied.

The high-resistance ring-shaped portion 51-4B is a separate, ring-shaped member arranged to surround the substrate W to be processed.

The electrostatic chuck device according to the third embodiment includes a separate, ring-shaped member being a high-resistance ring-shaped portion 51-4B.

As described above, also in the electrostatic chuck device according to the third embodiment with being a separate, ring-shaped member 51-4B being a high-resistance ring-shaped portion, a minute current I_{J-R} is generated when a DC voltage is applied to the ESC electrode 30 to generate the JR force. Compared with the above embodiment in which the high-resistance ring-shaped portion is integrated, in the electrostatic chuck device according to the third embodiment, the suppression effect of the leakage current I_{Leak} is further improved, and thereby the uniformity of plasma near the edge of the wafer W is further improved.

The electrostatic chuck device according to the third embodiment includes a separate, ring-shaped member 51-4B as a high-resistance ring-shaped portion, and is designed to reduce the leakage current I_{Leak}, thereby improving the uniformity of plasma near the edge of the wafer W.

The material of the ring member 51-4B has preferably plasma resistant and high-resistance and may be the same material as the stage 50-4. For example, it can be aluminum nitride (AlN). To increase the resistance, the back surface of the ring-shaped member 51-4B in contact with the stage 50-4 can be configured with multiple protrusions to reduce the contact area. For example, embossing may be applied. A constitution with multiple protrusions on the back surface of the ring-shaped member 51-4B corresponds to the effect of reducing the area S in formula (1). In addition, the ring-shaped member 51-4B is preferably made of a material with a small dielectric constant or thermal conductivity as a material whose temperature does not rise easily.

The ring-shaped convex portion 51-4B as a high-resistance ring-shaped portion is preferably made of a high-resistance material with a higher volume resistivity than the stage material in the portion (wafer contact portion) 51-4A between the substrate attached area 50-4A and the ESC electrode 30.

In the electrostatic chuck device shown in FIG. 5A, a heater (see, reference sign 28 in FIG. 7) may be provided below the ESC electrode 30 in the stage 50-4.

FIG. 5B is a schematic cross-sectional view of an electrostatic chuck device with a stage 50-5 in which a ring-shaped member 51-4B is mounted on the stage 50 shown in FIGS. 1A and 1B.

The electrostatic chuck device 105 shown in FIG. 5B is an electrostatic chuck device used in a plasma space. A stage 50-5 in the electrostatic chuck device 105 has a stage 50 shown in FIGS. 1A and 1B and a separate, ring-shaped member 51-4B. The electrostatic chuck device 105 includes a stage 50-5 having on its upper surface 50a a circular substrate attached area 50A (where D_{S} is the diameter of the area) to which a circular substrate W to be processed is electrostatically attached, and an ESC electrode 30 embedded in the stage 50, having a diameter D_{E1} larger than the diameter D_{S} of the substrate attached area 50A, and arranged concentrically with the center O of the substrate attached area 50A in plan view. The substrate W to be processed is electrostatically attached to the upper surface 50a of the stage 50-5 by the Johnsen-Rahbek force by applying a DC voltage to the ESC electrode 30. The stage 50-5 has a ring-shaped member 51-4B in a ring-shaped outer peripheral area 50B arranged adjacent to the outside of the substrate adsorption area 50A in plan view.
The electrostatic chuck device 105 shown in FIG. 5B includes a characteristic of the electrostatic chuck device 100 shown in FIGS. 1A and 1B and a characteristic of the electrostatic chuck device 104 shown in FIG. 5A.

The material of the ring-shaped member 51-4B may be the same as the material of the high-resistance ring-shaped portion 51B.

In the electrostatic chuck device shown in FIG. 5B, a heater (see, reference sign 28 in FIG. 7) may be provided below the ESC electrode 30 in the stage 50.

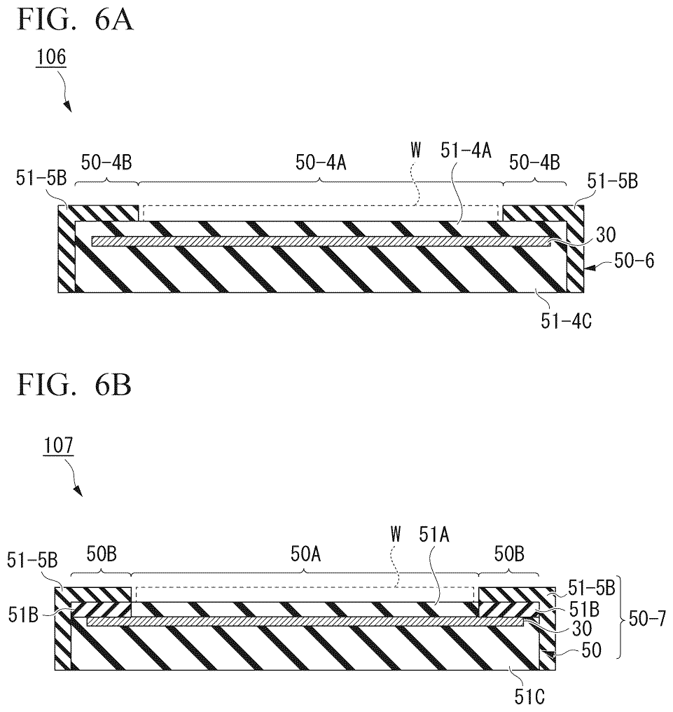

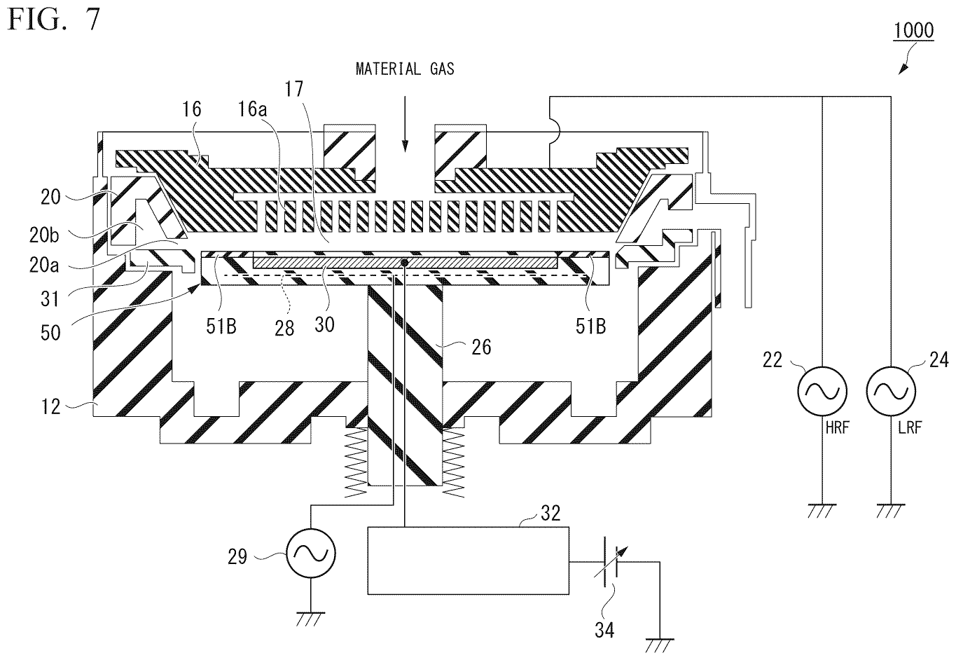

The electrostatic chuck devices 106 and 107 shown in FIGS. 6A and 6B correspond to the electrostatic chuck devices 104 and 105 shown in FIGS. 5A and 5B, respectively, and are configured with a ring-shaped member 51-5B that covers up to the side of the stage 50.

In case the plasma extends to the side of the stage 50, the ring-shaped member 51-5B is preferably configured to cover the side of the stage 50 to reduce the leakage current from the side of stage 50.

In the electrostatic chuck device shown in FIGS. 6A and 6B, a heater (see, reference sign 28 in FIG. 7) may be provided below the ESC electrode 30 in the stage 50-6 or the stage 50-7.

FIG. 7 is a schematic cross-sectional view showing an example of a substrate processing apparatus equipped with the electrostatic chuck device described above. FIG. 7 shows an example of a substrate processing apparatus equipped with the electrostatic chuck device 100 shown in FIGS. 1A and 1B as an electrostatic chuck device.

The substrate processing device 1000 shown in FIG. 7 includes a chamber 12. The chamber 12 is provided with a stage 50 of the present disclosure and an upper electrode (showerhead) 16 positioned opposite the stage 50. The upper electrode 16 is provided with a plurality of slits 16a. A material gas is supplied between the stage 50 and the upper electrode 16 through each slit 16a.

An exhaust duct 20 is fixed to the chamber 12 and the upper electrode 16 via an O-ring. An exhaust duct 20 surrounds a space between the upper electrode 16 and the stage 50. The gas supplied between the upper electrode 16 and the stage 50 and used for substrate processing is discharged outside the chamber 12 through the exhaust duct 20.

A flow control ring (FCR) 31 is provided to direct gas from a processing space 17 to the annular channel 20b. For example, an FCR 31 is positioned on the chamber 12 and an O-ring is placed between them. The FCR 31 and the exhaust duct 20 provide a slit 20a, and the gas fed into the processing space 17 is directed through the slit 20a into the annular channel 20b.

A first AC power supply 22 and a second AC power supply 24 are connected to the upper electrode 16. The first AC power supply 22 supplies AC power at the first frequency. The second AC power supply 24 supplies AC power at the second frequency which is lower than the first frequency. The first frequency can be in the range of, for example, 1 to 30 MHz. This frequency band is called HRF (High Radio Frequency). The first AC power supply 22 provides AC power of, for example, 13.56 MHz. The second frequency may be in the range of 100 kHz to 1000 kHz. This frequency band is called Low Radio Frequency (LRF). The second AC power supply 24 provides AC power of, for example, 430 KHz.

The stage 50 is supported by a support 26. The stage 50 and the support 26 are integrated into a susceptor. A heater 28 is embedded in the stage 50. The heater 28 is provided, for example, in a spiral form in a plan view. The heater 28 is connected to the power supply 29 via a wiring passing through the support 26. The power supply 29 supplies current to the heater 28, which heats the stage 50 and also heats the substrate on the stage 50.

In the example shown in FIG. 7, the heater 28 is built in the stage 50, but it is not limited to this configuration and may be placed outside the stage 50 to heat the wafer W.

An ESC electrode 30 is provided in the stage 50. The ESC electrode 30 is connected to a filter circuit 32 via a wiring passing through the support 26. The ESC electrode 30 and the DC power supply 34 are connected via the filter circuit 32. A DC power supply 34 applies a voltage to the ESC electrode 30 to provide an electrostatic chuck.

The filter circuit 32 includes a capacitor that connects the ESC electrode 30 and the ground. This capacitor is mainly provided to pass AC power at the first frequency supplied by the first AC power supply 22.

The filter circuit 32 includes a coil and a capacitor. A wiring connecting the ESC electrode 30 and the capacitor is connected to the ground via the coil and the capacitor. A series circuit of the coil and the capacitor connects the ESC electrode 30 to the ground. This capacitor and coil are provided mainly to pass the second frequency AC power supplied by the second AC power supply 24.

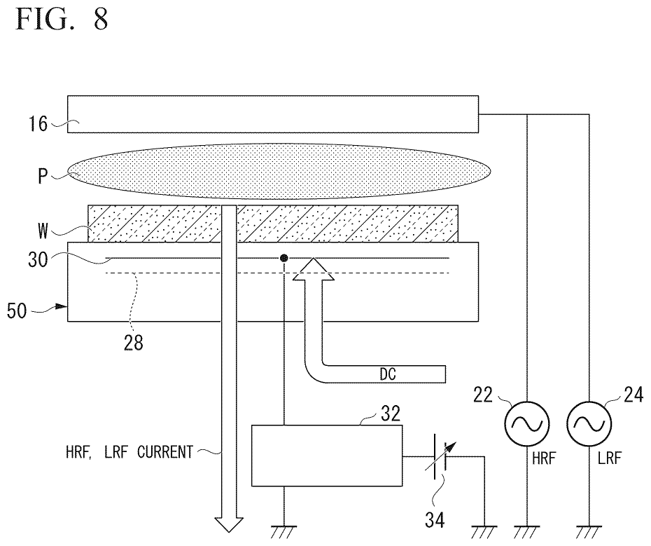

The operation of the substrate processing apparatus during substrate processing is described. FIG. 8 is a diagram simply expressing the configuration of FIG. 7 in order to explain the operation during substrate processing in an easy-to-understand manner. Substrate processing is started in a state where a substrate W to be processed is placed on the stage 50. The substrate W to be processed is, for example, a Si wafer. The substrate W to be processed is heated to a predetermined temperature by the heater 28. While supplying a material gas between the upper electrode 16 and the stage 50, the AC power at the first frequency is supplied to the upper electrode 16 by the first AC power supply 24. Thereby, a plasma P is generated between the upper electrode 16 and the stage 50. When a ESC voltage is applied to the ESC electrode 30 by the DC power supply 34 in this state, a ESC (DC) current flows through a plasma between electrodes and Johnsen-Rahbek force is generated by the induced charged polarization at an interfacial gap between the substrate W to be processed and the stage 50, and the substrate W to be processed is electrostatically attached to the stage 50. Thereby, electrostatic chucking can be performed. In the substrate processing apparatus 1000 shown in the figure, since there is one ESC electrode 30, an electrostatic chuck can be provided only when plasma is generated.

The processing by the substrate processing apparatus 1000 shown in FIG. 7 is not particularly limited if it involves plasma processing. For example, the substrate processing apparatus 1000 may be utilized as a plasma excited atomic layer deposition apparatus (PEALD apparatus) or as a plasma excited chemical vapor deposition apparatus (PECVD apparatus).

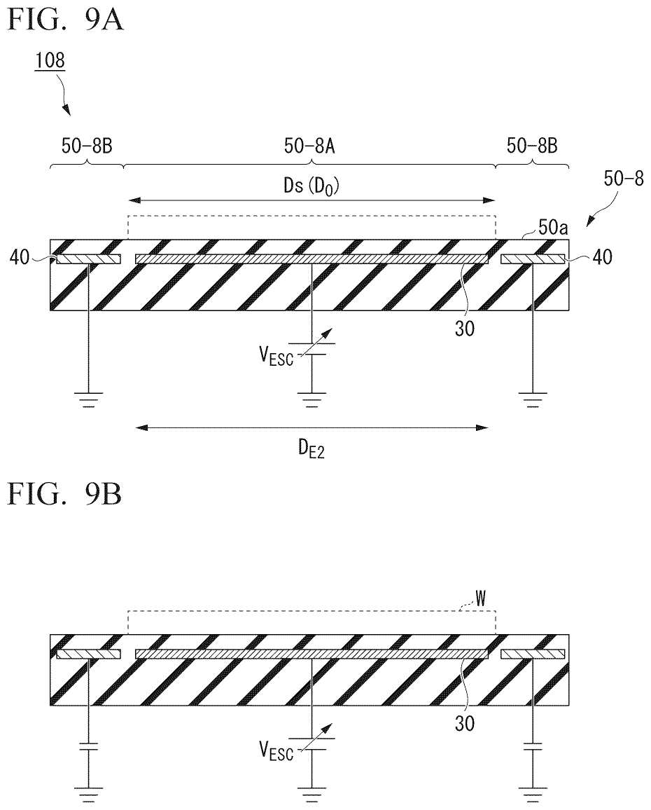

FIGS. 9A and 9B are schematic cross-sectional views of the electrostatic chuck device according to the fourth embodiment. Components in common with those described above are described using the reference signs used in the above figures.

The electrostatic chuck device 108 shown in FIG. 9A is an electrostatic chuck device used in a plasma space. The electrostatic chuck device 108 includes a stage 50-8 having on its upper surface 50a a circular substrate attached area 50-8A (where D_{S} is the diameter of the area) to which a circular substrate W to be processed is electrostatically attached, an ESC electrode 30 embedded in the stage 50-8, having a diameter D_{E2} which is smaller than or approximately the same as the diameter D_{S} of the substrate attached area 50-8A, and arranged concentrically with the center O of the substrate attached area 50-8A in plan view, and an RF electrode 40 for plasma generation which is embedded in the stage 50-8 at the same depth as the ESC electrode 30, and is in an outer portion 50-8B arranged outside the substrate attached area 50-8A in plan view. The substrate W to be processed is electrostatically attached to the upper surface 50a of the stage 50-8 by the Johnsen-Rahbek force by applying a DC voltage to the ESC electrode 30.

The electrostatic chuck device according to the fourth embodiment is, for example, a constitution in which an electrode of capacitive coupled plasma also serves as an RF electrode. When the ESC electrode is made smaller, no current flows to the outer peripheral portion of the wafer. However, since the RF electrode is determined by the size of the ESC electrode, the plasma size also becomes smaller and the uniformity of the plasma with respect to the wafer is also deteriorated. Therefore, the RF electrode is embedded in the stage so as to be ground with respect to the ESC electrode. As an ESC electrode, the size can be reduced to reduce the current at the outer peripheral portion, but this deteriorates the uniformity of the plasma, and to compensate for this, an RF electrode is embedded in the stage.

As shown in FIG. 9B, no ESC voltage is applied to the RF electrode 40, and a capacitor and a coil are connected so that the impedance seen from the ground or the ESC electrode 30 and the RF electrode 40 is equal.

In the electrostatic chuck device 108, no ESC voltage is applied to the RF electrode 40, so no leakage current is generated. Therefore, the uniformity of the plasma near the edge of the wafer W is maintained.

The electrostatic chuck devices shown in FIGS. 9A and 9B can be used in the substrate processing apparatus shown in FIG. 7.

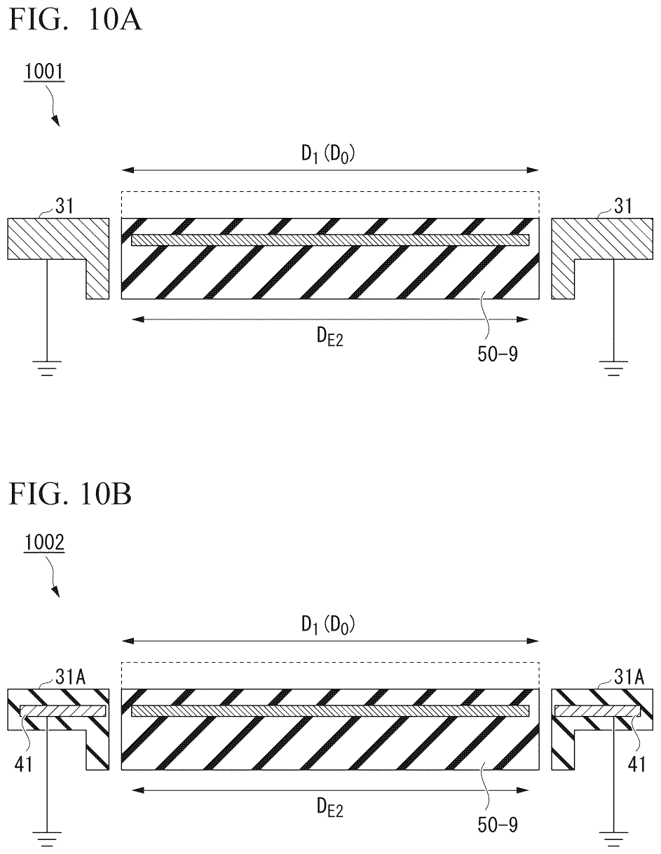

FIGS. 10A and 10B are schematic cross-sectional views of a part of the substrate processing apparatus in the vicinity of the electrostatic chuck unit. Components in common with those described above are described using the reference signs used in the figures used in the above.

The substrate processing apparatus 1001 shown in FIG. 10A includes an electrostatic chuck device used in a plasma space. The electrostatic chuck device includes a stage 50-9 having on its upper surface a circular substrate attached area (where D₁ is the diameter of the area) to which a circular substrate W to be processed (where D₀ is the diameter) is electrostatically attached, and an ESC electrode 30 embedded in the stage 50-9, having a diameter D_{E2} which is smaller than or approximately the same as the diameter D₁ of the substrate attached area, and arranged concentrically with the center O of the substrate attached area in plan view. The diameter D₁ in the circular substrate attached area (the upper surface) is equal to the diameter D₀ of the substrate W to be processed within a range of ±5 mm.

In the substrate processing apparatus 1001, the flow control ring 31 (see, FIG. 8) is made of metal and acts as an RF electrode for plasma generation.

The RF electrodes shown in FIGS. 9A and 9B were built into the stage. In the constitution shown in FIGS. 10A and 10B, the stage itself was made to be almost the same size as the wafer, and separately, in the substrate processing apparatus equipped with a flow control ring (FCR), the flow control ring was installed in the same manner as the ring-shaped member described above to control the spread of plasma. The flow control ring can be made of metal (FIG. 10A) or ceramic (FIG. 10B). If it is made of ceramic, a RF electrode is embedded in the flow control ring to achieve the same effect as in FIGS. 9A and 9B.

In the substrate processing unit 1001, the flow control ring 31 functions as an RF electrode. No ESC voltage is applied, so no leakage current is generated. Therefore, the uniformity of the plasma near the edge of the wafer W is maintained.

The substrate processing apparatus 1002 shown in FIG. 10B includes an electrostatic chuck device used in a plasma space. The electrostatic chuck device includes a stage 50-9 having on its upper surface a circular substrate attached area (where D₁ is the diameter of the area) to which a circular substrate W to be processed (where D₀ is the diameter) is electrostatically attached, and an ESC electrode 30 embedded in the stage 50-9, having a diameter D_{E2} which is smaller than or approximately the same as the diameter D₁ of the substrate attached area, and arranged concentrically with the center O of the substrate attached area in plan view. The diameter D₁ of the substrate attached area (the upper surface) is equal to the diameter D₀ of the substrate W to be processed within a range of ±5 mm.

In the substrate processing apparatus 1002, the flow control ring 31A (see, FIG. 8) is made of ceramic and an RF electrode 41 for plasma generation is built in the flow control ring 31A.

In the substrate processing apparatus 1002, an RF electrode 41 is built in the flow control ring 31 A. No ESC voltage is applied, so no leakage current is generated. Therefore, the uniformity of the plasma near the edge of the wafer W is maintained.

1. An electrostatic chuck device used in a plasma space, comprising:
a stage having on its upper surface a circular substrate attached area (where D_{S} is the diameter of the area) to which a circular substrate to be processed is electrostatically attached; and
an ESC electrode embedded in the stage, having a diameter D_{E1} larger than the diameter D_{S} of the substrate attached area, and arranged concentrically with the center of the substrate attached area in plan view;
wherein the substrate to be processed is electrostatically attached to the substrate attached area of the stage by the Johnsen-Rahbek force by applying a DC voltage to the ESC electrode, and the stage includes a high-resistance ring-shaped portion in an outer portion arranged outside the substrate attached area in plan view, which is configured to suppress current leaking from the outer portion to the plasma space when the DC voltage is applied.

2. The electrostatic chuck device according to claim 1, comprising a heater below the ESC electrode in the stage.

3. The electrostatic chuck device according to claim 1, wherein the high-resistance ring-shaped portion is made of a high-resistance material having a higher volume resistivity than that of the material of the portion of the stage between the substrate attached area and the ESC electrode.

4. The electrostatic chuck device according to claim 3, wherein the high-resistance material of the high-resistance ring-shaped portion includes the same base material as the material of a portion other than the high-resistance ring-shaped portion, and the concentration of impurity elements in the high-resistance material of the high-resistance ring-shaped portion is different from that in the material of the portion other than the high-resistance ring-shaped portion.

5. The electrostatic chuck device according to claim 4, wherein the high-resistance material of the high-resistance ring-shaped portion is aluminum nitride.

6. The electrostatic chuck device according to claim 1, wherein the high-resistance ring-shaped portion is a ring-shaped convex portion disposed so as to surround the substrate to be processed and protruding upward from the substrate attached area.

7. The electrostatic chuck device according to claim 6, wherein the ring-shaped convex portion is made of a high-resistance material having a higher volume resistivity than that of the material of the portion of the stage between the substrate attached area and the ESC electrode.

8. The electrostatic chuck device according to claim 7, wherein the high-resistance material of the ring-shaped convex portion includes the same base material as the material of a portion other than the ring-shaped convex portion, and the concentration of impurity elements in the high-resistance material of the ring-shaped convex portion is different from that in the material of the portion other than the ring-shaped convex portion.

9. The electrostatic chuck device according to claim 1, wherein the high-resistance ring-shaped portion is a separate, ring-shaped member disposed so as to surround the substrate to be processed.

10. The electrostatic chuck device according to claim 9, wherein the ring-shaped member includes multiple protrusions on its back surface.

11. The electrostatic chuck device according to claim 9, wherein the ring-shaped member is made of a high-resistance material having a higher volume resistivity than that of the material of the portion of the stage between the substrate attached area and the ESC electrode.

12. The electrostatic chuck device according to claim 3, wherein, as the high-resistance ring-shaped portion, a ring-shaped member is separately disposed on the high-resistance ring-shaped portion made of a high-resistance material so as to surround the substrate to be processed.

13. The electrostatic chuck device according to claim 12, wherein the ring-shaped member includes multiple protrusions on its back surface.

14. The electrostatic chuck device according to claim 13, wherein the material of the ring-shaped member is the same as that of the high-resistance ring-shaped portion made of a high-resistance material.

15. An electrostatic chuck device used in a plasma space, comprising:
a stage having on its upper surface a circular substrate attached area (where D_{S} is the diameter of the area) to which a circular substrate to be processed is electrostatically attached;
an ESC electrode embedded in the stage, having a diameter D_{E2} which is smaller than or approximately the same as the diameter D_{S} of the substrate attached area, and arranged concentrically with the center of the substrate attached area in plan view; and
an RF electrode for plasma generation which is embedded in the stage at the same depth as the ESC electrode, and is in an outer portion arranged outside the substrate attached area in plan view;
wherein the substrate to be processed is electrostatically attached to the substrate attached area of the stage by the Johnsen-Rahbek force by applying a DC voltage to the ESC electrode.

16. The electrostatic chuck device according to claim 15, wherein the RF electrode is grounded through a matching circuit including a capacitor and/or a coil so that the RF electrode and the ESC electrode have equivalent impedance.

17. A substrate processing apparatus, comprising:
a chamber;
an electrostatic chuck device according to claim 1, provided in the chamber; and
a shower head provided above the electrostatic chuck device.

18. A substrate processing apparatus, comprising:
a chamber;
an electrostatic chuck device according to claim 15, provided in the chamber; and
a shower head provided above the electrostatic chuck device.

19. A substrate processing apparatus, comprising:
a chamber;
an electrostatic chuck device provided in the chamber;
a shower head provided above the electrostatic chuck device; and
a flow control ring having a shape surrounding the electrostatic chuck device,
wherein the electrostatic chuck device includes a stage having on its upper surface a circular substrate attached area (where D₁ is the diameter of the area) to which a circular substrate to be processed (where D₀ is the diameter of the substrate) is electrostatically attached, and an ESC electrode embedded in the stage, having a diameter D_{E2} which is smaller than or approximately the same as the diameter D₁ of the substrate attached area, and arranged concentrically with the center of the substrate attached area in plan view, and
wherein the diameter D₁ in the substrate attached area is equal to the diameter D₀ of the substrate to be processed within a range of ±5 mm, and the flow control ring is made of metal and acts as an RF electrode for plasma generation.

20. A substrate processing apparatus, comprising:
a chamber;
an electrostatic chuck device provided in the chamber;
a shower head provided above the electrostatic chuck device; and
a flow control ring having a shape surrounding the electrostatic chuck device,
wherein the electrostatic chuck device includes a stage having on its upper surface a circular substrate attached area (where D₁ is the diameter of the area) to which a circular substrate to be processed (where D₀ is the diameter of the substrate) is electrostatically attached, and an ESC electrode embedded in the stage, having a diameter D_{E2} which is smaller than or approximately the same as the diameter D₁ of the substrate attached area, and arranged concentrically with the center of the substrate attached area in plan view, and
wherein the diameter D₁ of the substrate attached area is equal to the diameter D₀ of the substrate to be processed within a range of ±5 mm, the flow control ring is made of ceramic, and an RF electrode for plasma generation is embedded in the flow control ring.
